(19) United States
(12) Patent Application Publication
(10) Pub. No.: US 2007/0253167 A1
(43) Pub. Date: Nov. 1, 2007

(54) Transparent substrate heat dissipater

(76) Inventor: Kuo Ching Chiang, Linkou Township (TW)

Correspondence Address: BIRCH STEWART KOLASCH & BIRCH, PO BOX 747, FALLS CHURCH, VA, 22040-0747, US

(21) Appl. No.: 11/819,124

(22) Filed: Jun. 25, 2007

Related U.S. Application Data
(63) Continuation-in-part of application No. 10/898,761, filed on Jul. 26, 2004, now abandoned.
(63) Continuation-in-part of application No. 10/900,766, filed on Jul. 28, 2004.

(51) Int. Cl. H05K 7/20; F28D 15/00

(52) U.S. Cl. 361/717; 165/104.33

(57) ABSTRACT

The present invention discloses a heat dissipater for a chamber comprising a substantially transparent substrate, a first substantially transparent conductive pattern formed over the substrate. At least one Peltier device is formed on the first substantially transparent conductive pattern. A second substantially transparent conductive pattern is then formed on the Peltier device, wherein electricity is applied to the Peltier device, current drives a heat transfer from inside of the chamber to outside.

### FIELD OF THE INVENTION

The present invention relates a heat dissipater, and more particularly, a heat dissipater with Peltier diode.

### BACKGROUND OF THE INVENTION

Recently, the issues of environmental protection is more serious than ever, the greenhouse effect and oil shortage impacts to the earth and global environment, continuously. Because of the issue mentioned above, manufactures endeavor to develop green product such as solar cell to save the energy. Solar cells are a kind of optoelectronic semiconductor device for transforming light into electricity.

Conventional thermal transfer occurs only through conduction. Heat transfer associates with carriage of the heat by a substance. Peltier effect is the reverse of the Seebeck effect. When a current is passed through two conductors such as metals or semiconductors (n-type and p-type) connected to each other at two junctions (Peltier junctions), a heat difference is created between the two junctions. Namely, current drives a heat transfer from one junction to the other, one junction cools off while the other heats up. When electrons flow from a region of high density to a region of low density, they expand and cool. The direction of transfer will be changed when the polarity is revised and thus the sign of the heat absorbed/evolved. The effect may transfer heat from one side of the device to the other. When current moves from the hotter end to the colder end, it is moving from a high to a low potential, so there is an evolution of energy.

Obliviously, what is desired is a cooler with energy saving properties.

### SUMMARY OF THE INVENTION

The present invention discloses a heat dissipater for a chamber comprising a substantially transparent substrate, a first substantially transparent conductive pattern formed over the substrate. At least one Peltier device is formed on the first substantially transparent conductive pattern. A second substantially transparent conductive pattern is then formed on the Peltier device, wherein electricity is applied to the Peltier device, current drives a heat transfer from inside of the chamber to outside, vise verse.

The material of the first and the second conductive patterns includes oxide containing metal, wherein the metal is one or more from Au, Zn, Ag, Pd, Pt, Rh, Ru, Cu, Fe, Ni, Co, Sn, Ti, In, Al, Ta, Ga, Ge and Sb. Preferably, the first and second conductive transparent patterns include Al2O3 doped therein. Solar cells are preferably coupled to the heat dissipater. The chamber could be a part of a building or a vehicle.

A heat dissipater comprises a semiconductor component; a first conductive layer formed over the semiconductor component; a Peltier device formed on the first conductive layer; and a second conductive layer formed on the Peltier device; wherein electricity is applied to the Peltier device, current drives a heat transfer from the junction of the first conductive layer to the junction of the second conductive layer. A heat sink is coupled to the second conductive layer. Preferably, the heat sink includes fins with rugged surface to increase the dissipation surface. The rugged surface can be formed by etching. The semiconductor includes due processors system. A first and a second catches are coupled to the due processors system; a cross processor interface coupled to the first and a second catches; a memory controller coupled to the cross processor interface.

The present invention discloses a heat dissipater for semiconductor assembly comprising at least one Peltier diode coupled to a least one surface of a semiconductor package having a die contain therein; an electricity lines coupled to the at least one Peltier diode; and wherein electricity is applied to the Peltier diode, current drives a heat transfer out of the semiconductor package. The heat dissipater further comprises a heat sink coupled to the at least one Peltier diode. The electricity lines comprise a first and a second conductive lines formed upper and lower of the Peltier diode.

### BRIEF DESCRIPTION OF THE DRAWINGS

FIG. 1A-1D illustrate the heat dissipation device for building window or vehicle window.

FIG. 2, 4 illustrate the dissipation device for semiconductor component.

FIG. 3 illustrates the dissipation device for due semiconductor processors system.

### DETAILED DESCRIPTION OF THE PREFERRED EMBODIMENTS

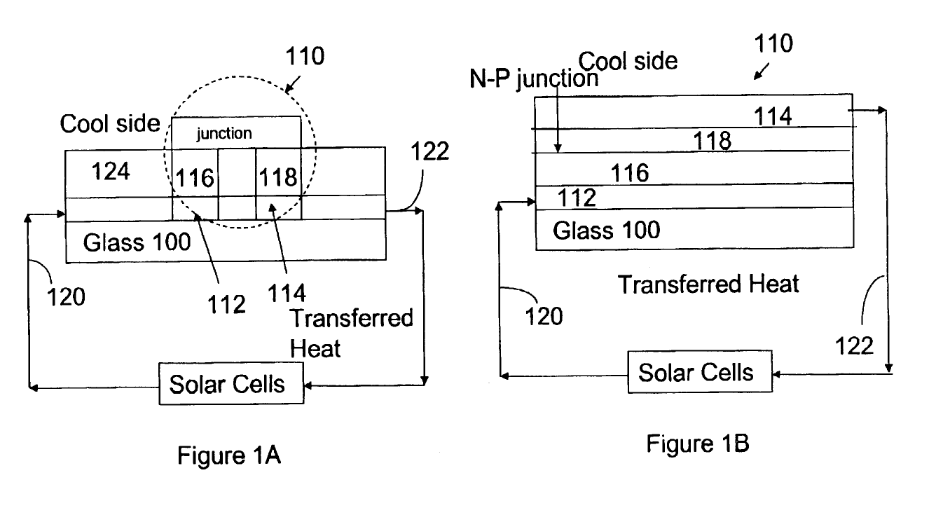

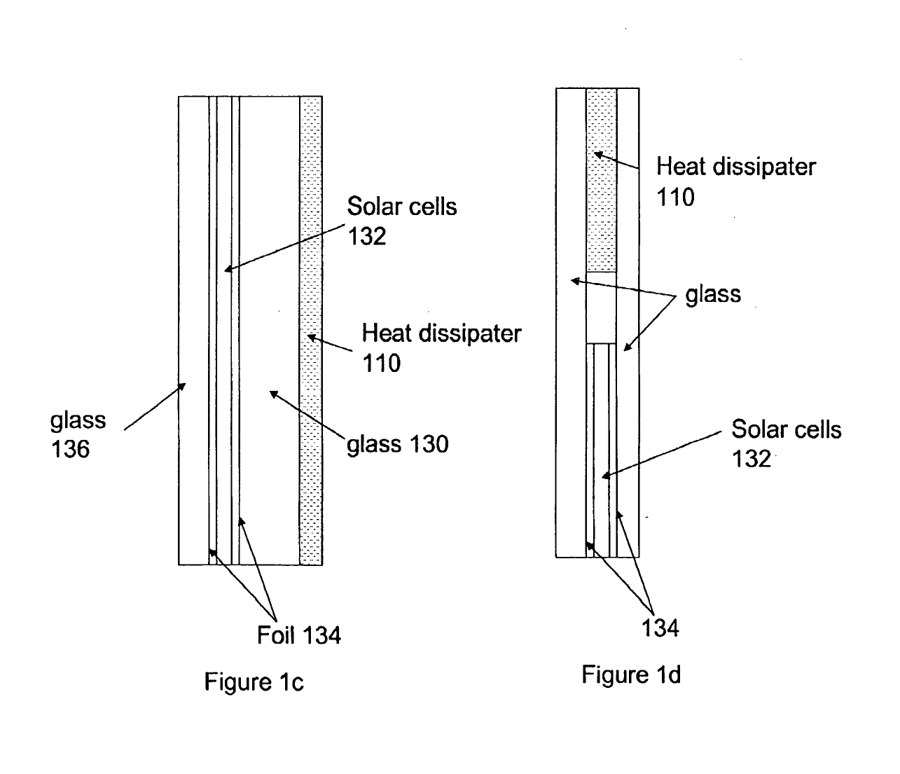

The present invention includes a substrate 100. Preferably, the substrate is substantially transparent, for example, glass, quartz or the like. At least one Peltier diode 110 is formed on the substrate, as shown in FIGS. 1A and 1B. The Peltier diode 110 includes a first electrode 112 and a second electrode 114, n-type and p-type semiconductors 116, 118 connected to each other at two junctions (Peltier junctions). The n-type and p-type semiconductors 116, 118 can be silicon layer or other III-V elements. The pattern can be formed by etching printing, or coating, as well known in the art. The conductive lines 120, 122 are coupled to the first electrode 112 and a second electrode 114, respectively. A heat difference is created between the two junctions. The current drives a heat transfer from one junction to the other, one junction cools off while the other heats up. Therefore, the heat may transfer from one side to another. An isolation material 124 may be filled between the first electrode 112 and a second electrode 114. It could be oxide or the like.

The electrical energy is coupled to the conductive lines 120, 122. The power could be provided by electricity, battery or solar cell. In one application, the present invention may be used for the window of building or house, or a vehicle. When the electricity is provided, the heat will be transferred from the inside of building (vehicle) to the outside to cool down the temperature within the building (vehicle), thereby saving the energy. The power consumption is far lower than the conventional air condition, Preferably, the electricity is supplied by the solar cells set outside the building (vehicle). When the weather is hot, generally, the solar radiation is strong. The solar cell could transfer the solar energy to electricity. Subsequently, the present invention uses the electricity to cool down the temperature in the house in lieu of the Peltier device (diode). The device may be employed as warmer when the electrode is reversed.

Preferably, the solar cells 132 maybe incorporated between dual glasses 130, 136, as shown in FIGS. 1c, and 1d. The protection foil 134 may be set adjacent to the solar cell 132. The heat dissipater 110 may be attached adjacent to one of the glass or between the glass 130 and the glass 136.

FIGS. 1A and 1B describe an embodiment of the present invention, the present invention comprises a transparent conductive pattern 120, 122 formed over the object 100, a protection layer (not shown) is coated on the pattern. One example of the object 100 is wind glass, rear glass, side glass of a vehicle, window of a building. In one example, a power source is coupled to the conductive pattern to remove fog, moisture on the glass.

The present invention could be set on the window of a building to cool down the temperature within the building. In order to form on the glass, preferably, the material is transparent or substantially transparent. The material for the conductive pattern includes oxide containing metal, wherein the metal can be selected one or more from Au, Ag, Pt, In, Ga, Al, Sn, Ge, Sb, Bi, Zn, and Pd. Some conductive materials formed by the method are transparent, if the pattern is attached on the glass or window, one may see through the window or glass. In this case, the conductive layer, usually composed by a material includes oxide containing metal or alloy, wherein the metal is preferable to select one or more metals from Au, Zn, Ag, Pd, Pt, Rh, Ru, Cu, Fe, Ni, Co, Sn, Ti, In, Al, Ta, Ga, Ge and Sb. Some of the transparent material includes oxide containing Zn with Al₂O₃ doped therein. This shape is constructed by using an adequate mask during the forming process of the transparent conducting layer.

The method for forming the transparent conductive layer includes ion beam method for film formation at low temperature, for example, the film can be formed with receptivity lower than 3×10⁴ Ω.cm at room temperature. Further, the RF magnetron sputtered thin film method could also be used. The transparent can be higher than 82%. It is well known in the field of forming thin film. Under the cost and production consideration, the method for forming, for example, indium tin oxide, could be formed at room temperature in wet atmosphere has an amorphous state, a desired pattern can be obtained at a high etching rate. After the film is formed and patterned, it is thermally treated at a temperature of about between 180 degree C. and 220 degree C. for about one hour to three hours to lower the film resistance and enhance its transmittance. Another formation is chemical solution coating method. The coating solution includes particles having an average particle diameter of 1 to 25 μm, silica particles having an average particle diameter of 1 to 25 μm, and a solvent. The weight ratio of the silica particles to the conductive particles is preferably in the range of 0.1 to 1. The conductive particles are preferably metallic particles of one or more metals selected from Au, Zn, Ag, Pd, Pt, Rh, Ru, Cu, Fe, Ni, Co, Sn, Ti, In, Al, Ta, Ga, Ge and Sb. The conductive particles can be obtained by reducing a salt of one or more kinds of the aforesaid metals in an alcohol/water mixed solvent. Heat treatment is performed at a temperature of higher than about 100 degree C. The silica particles may improve the conductivity of the resulting conductive film. The metallic particles are approximately contained in amounts of 0.1 to 5% by weight in the conductive film coating liquid.

The transparent conductive film can be formed by applying the liquid on a substrate, drying it to form a transparent conductive particle layer, then applying the coating liquid for forming a transparent film onto the fine particle layer to form a transparent film on the particle layer. The coating liquid for forming a transparent conductive layer is applied onto a substrate by a method of dipping, spinning, spraying, roll coating, flexographic printing or the like and then drying the liquid at a temperature of room temperature to about 90.degree. C. After drying, the coating film is curing by heated at a temperature of not lower than 100 degree C. or irradiated with an electromagnetic wave or in the gas atmosphere. The present invention uses the Peltier effect to create a heat flux between the junctions of two different types of semiconductor materials. It transfers heat from one side of the device to the other side with consumption of electrical energy.

A moisture removal power source may be coupled to the configuration via line for providing heat to the pattern to remove fog or moisture on the glass or window. Thus, in some case, the configuration includes dual functions including heat pump and acting as means for removing fog or moisture.

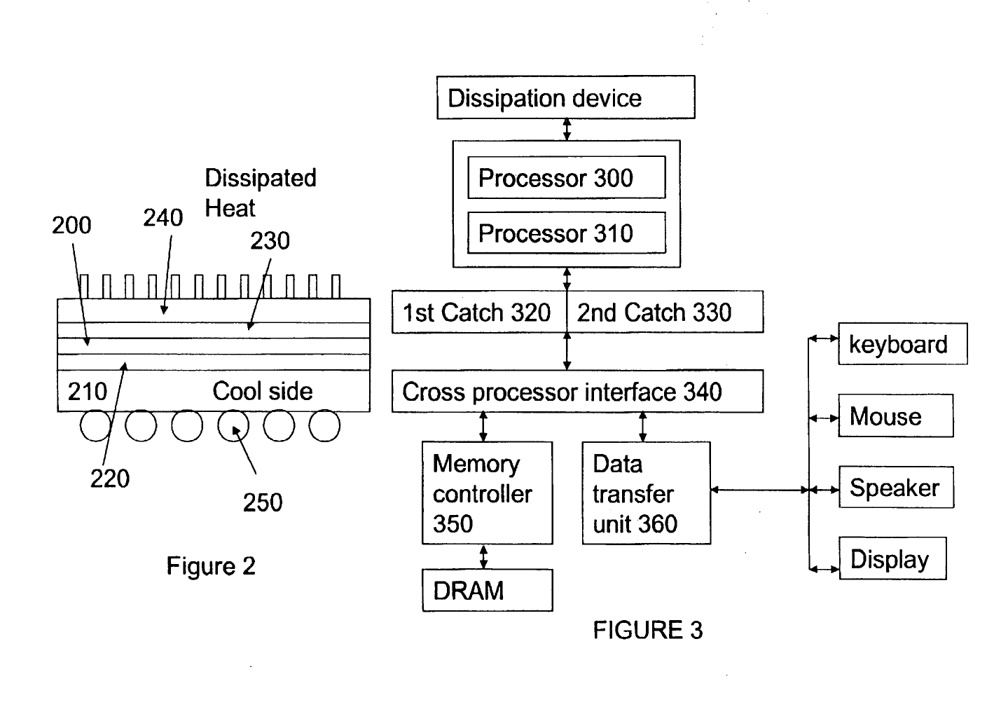

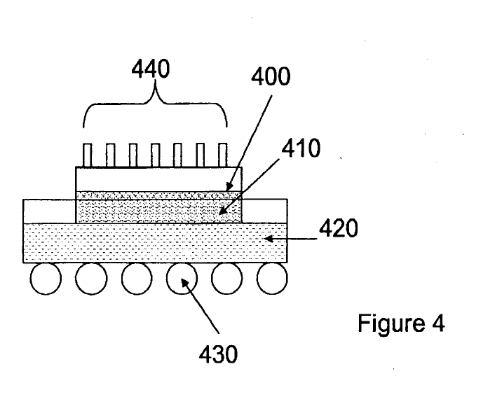

In another embodiment, the Peltier device is used to act the heat pump for processor for computer, notebook or mobile device such as cellar, PDA, GPS. Please refer to FIG. 2, the Peltier device 200 is coupled to the semiconductor chip assembly 210 having die contained therein. In one case, it Peltier device 200 is coated on the outside of BGA device having conductive balls 250. The flip-chip is used for illustration only, not limits the scope of the present invention. A first conductive line 220, Peltier device 200, and a second conductive line 230 are formed on the semiconductor component assembly. Most of the thermal is generated by the chip or processor of the computer, notebook or mobile device. The pattern of the first conductive line 220, Peltier device 200, and a second conductive line 230 can be formed by CVD, sputtering or coating. In order to improve the performance of thermal dissipation, a heat sink 240 may be attached on the second conductive line 230. Accordingly, the heat sink is formed on the hot side, therefore, after the electricity is provided to the first conductive line 220, and the second conductive line 230. The current drives a heat transfer from semiconductor component 210 to the heat sink side, one junction cools off while the other heats up. Especially, the scheme may be used to the due processors system, as shown in FIG. 3. In the case, the heat dissipater is formed outside of the semiconductor package assembly. Alternatively, referring to FIG. 4, the heat dissipater 400 is attached over the die 410 on a substrate 420 having conductive balls 430. The heat sink 440 is attached over the heat dissipater 400. In the flip-chip scheme, the heat dissipater 400 may be formed over the backside surface of the wafer before assembly. The backside surface refers to the surface without active area.

The electronic system includes a first processor 300 and a second processor 310. A first catch 320 and a second catch 330 are coupled to the first processor 300 and a second processor 310, respectively. Cross process interface 340 is coupled to the first catch 320 and a second catch 330. A memory controller 350 and a data transfer unit 360 are coupled to the cross process interface 340. The cross process interface 340 is used to determine how to transfer the date in/out to/from the first processor 300 and a second processor 310. The DRAM is coupled to the memory controller 350. A plurality of periphery device such as Mic., speaker, keyboard, mouse are coupled to the data transfer unit 360. A fan may be optionally coupled to the heat dissipation device mentioned in FIG. 2. If the system is single chip system, the cross-process interface is omitted. If the system is communication device, RF is necessary. Therefore, the present invention discloses a thermal solution for a computer system including a heat dissipater mentioned above coupled to the CPU to dissipate the thermal generated by the CPU.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure. While the preferred embodiment of the invention has been illustrated and described, it will be appreciated that various changes can be made therein without departing from the spirit and scope of the invention.

What is claimed is:

1. A heat dissipater for a window of an object, comprising:
a substantially transparent substrate;
a first substantially transparent conductive pattern formed over said substrate;
a Peltier diode formed on said first substantially transparent conductive pattern; and
a second substantially transparent conductive pattern formed on said Peltier device, wherein electricity is applied to said Peltier diode, current drives a heat transfer from said object to outside, vise verse.

2. The heat dissipater of claim 1, wherein the material of said first and said second conductive patterns includes oxide containing metal, wherein said metal is one or more from Au, Zn, Ag, Pd, Pt, Rh, Ru, Cu, Fe, Ni, Co, Sn, Ti, In, Al, Ta, Ga, Ge and Sb.

3. The heat dissipater of claim 2, wherein said first and second conductive transparent patterns include Al₂O₃ doped therein.

4. The heat dissipater claim 1, further comprising solar cells coupled to said heat dissipater.

5. The heat dissipater of claim 1, wherein said object is a building.

6. The heat dissipater claim 1, wherein said object is a vehicle.

7. A heat dissipater for semiconductor chip comprising: at least one Peltier diode coupled to one surface of a semiconductor package having a die contain therein; an electricity lines coupled to said at least one Peltier diode; and wherein electricity is applied to said Peltier diode, current drives a heat transfer out of said semiconductor package.

8. The heat dissipater of claim 7, further comprising a heat sink coupled to said at least one Peltier diode.

9. The heat dissipater of claim 7, wherein said heat sink includes fins with rugged surface to increase the dissipation surface.

10. The heat dissipater of claim 7, wherein said semiconductor includes due processors system.

11. The heat dissipater of claim 10, further comprising a first and a second catches coupled to said due processors system; a cross processor interface coupled to said first and a second catches; a memory controller coupled to said cross processor interface.

12. The heat dissipater of claim 7, wherein said electricity lines comprise a first and a second conductive lines formed upper and lower of said Peltier diode.

13. A heat dissipater for semiconductor chip comprising: at least one Peltier diode coupled to backside surface of a semiconductor die over a substrate; conductive balls formed at the lower surface of said substrate; electricity lines coupled to said at least one Peltier diode; and wherein electricity is applied to said Peltier diode, current drives a heat transfer out of said semiconductor die.

14. The heat dissipater of claim 13, further comprising a heat sink coupled to said at least one Peltier diode.

14. The heat dissipater of claim 14, wherein said heat sink includes fins with rugged surface to increase the dissipation surface.

15. The heat dissipater of claim 13, wherein said electricity lines comprise a first and a second conductive lines coupled to said Peltier diode.
